(19) United States
(12) Patent Application Publication
(10) Pub. No.: US 2016/0204283 A1
(43) Pub. Date: Jul. 14, 2016

(54) PHOTOVOLTAIC CELL AND METHOD OF FABRICATING THE SAME

(71) Applicant: RAMOT AT TEL-AVIV UNIVERSITY LTD., Tel-Aviv (IL)

(72) Inventors: Fernando PATOLSKY, Rechovot (IL); Alon KOSLOFF, Tel-Aviv (IL)

(21) Appl. No.: 14/912,407

(22) PCT Filed: Aug. 11, 2014
(86) PCT No.: PCT/IL2014/050721

§ 371 Date: Feb. 17, 2016

Related U.S. Application Data
(60) Provisional application No. 61/867,082, filed on Aug. 18, 2013.

(51) Int. Cl. H01L 31/028; H01L 31/0224; H01L 31/18; H01L 31/0352; H01L 31/0745

(52) U.S. Cl. CPC H01L 31/028; H01L 31/035227; H01L 31/03529; H01L 31/0745; H01L 31/1812; H01L 31/022425

(57) ABSTRACT

A photovoltaic cell device is disclosed. The device comprises: an active region having a plurality of spaced-apart elongated nanostructures aligned vertically with respect to an electrically conductive substrate, wherein each elongated nanostructure has at least one p-n junction characterized by a bandgap within the electromagnetic spectrum, and is coated by an electrically conductive layer being electrically isolated from the substrate.

### RELATED APPLICATION

This application claims the benefit of priority of U.S. Provisional Patent Application No. 61/867,082 filed Aug. 18, 2013, the contents of which are incorporated herein by reference in their entirety.

### FIELD AND BACKGROUND OF THE INVENTION

The present invention, in some embodiments thereof, relates to optoelectronics and, more particularly, but not exclusively, to a photovoltaic cell and method of fabricating the same.

Photovoltaic (PV) cells or solar cells are optoelectronic devices in which an incident photonic energy such as sunlight is converted to electrical power. An importance of PV cells is defined by increasing cost of fossil oil, adverse effect of pollution on human health and on environment and a prospect of future depletion of oil reserves. Silicon, gallium arsenide, and multi-junction devices are under research and development.

A conventional PV cell may be a p-n junction diode capable of generating electricity in the presence of sunlight. It is often made of crystalline silicon (e.g., polycrystalline silicon) doped with elements from either group III or group V on the periodic table. When these dopant atoms are added to the silicon, they take the place of silicon atoms in the crystalline lattice and bond with the neighboring silicon atoms in almost the same way as the silicon atom that was originally there. However, because these dopants do not have the same number of valence electrons as silicon atoms, extra electrons or holes become present in the crystal lattice. Upon absorbing a photon that carries an energy that is at least the same as the band gap energy of the silicon, the electrons become free. The electrons and holes freely move around within the solid silicon material, making silicon conductive. The closer the absorption event is to the p-n junction, the greater the mobility of the electron-hole pair.

Conventional PV cells are fabricated by sandwiching a semiconductor p-n junction between a light transmissive electrode and an additional electrode. When a photon enters into the p-n junction under an appropriate bias voltage, electron-hole separation takes place and photocurrent occurs.

Conventional multi-junction PVCs, also known as or tandem cells, include multiple p-n junctions, each junction comprising a different bandgap material. A multi-junction PVC is relatively efficient, and may absorb a large portion of the solar spectrum. The multi-junction cell may be epitaxially grown, with the larger bandgap junctions on top of the lower bandgap junctions.

### SUMMARY OF THE INVENTION

According to an aspect of some embodiments of the present invention there is provided a photovoltaic cell, comprising: an active region having a plurality of spaced-apart elongated nanostructures aligned vertically with respect to an electrically conductive substrate, wherein each elongated nanostructure has at least one p-n junction characterized by a bandgap within the electromagnetic spectrum, and is coated by an electrically conductive layer being electrically isolated from the substrate; and electronic circuitry for extracting from the substrate and the conductive layer electrical current and/or voltage generated responsively to light incident on the active region.

According to an aspect of some embodiments of the present invention there is provided a method of harvesting solar energy, comprising: exposing an active region of a photovoltaic cell to solar radiation, the active region having a plurality of spaced-apart elongated nanostructures aligned vertically with respect to an electrically conductive substrate, wherein each elongated nanostructure has at least one p-n junction characterized by a bandgap within the electromagnetic spectrum, and is coated by an electrically conductive layer being electrically isolated from the substrate; and extracting from the active region electrical current and/or voltage responsively to the solar radiation.

According to an aspect of some embodiments of the present invention there is provided a method of fabricating a photovoltaic cell, comprising: growing on an electrically conductive substrate a plurality of spaced-apart elongated nanostructures aligned vertically with respect to the substrate, and having has at least one p-n junction characterized by a bandgap within the electromagnetic spectrum; applying an electrically insulating layer on the substrate at a base level of the elongated nanostructures; and coating each of at least a portion of the elongated nanostructures by an electrically conductive layer, the electrically conductive layer being electrically isolated from the substrate by the electrically insulating layer.

According to some embodiments of the invention the photovoltaic cell wherein the electrically conductive layer comprises a metal.

According to some embodiments of the invention the electrically conductive layer comprises a metal silicide.

According to some embodiments of the invention the silicide comprises at least one silicide selected from the group consisting of cobalt silicide, palladium silicide, platinum silicide, iron silicide, titanium silicide and tungsten silicide.

According to some embodiments of the invention the at least one p-n junction comprises a plurality of p-n junctions.

According to some embodiments of the invention the at least one p-n junction comprises a p-type region and an n-type region arranged generally concentrically in a core-shell relation.

According to some embodiments of the invention at least a few of the p-type regions and n-type regions are graded thereamongst.

According to some embodiments of the invention the at least one p-n junction comprises a plurality of p-type regions and n-type regions arranged to form a plurality of generally concentric shells, wherein at least a few of the p-type regions and n-type regions are made of a AxB1-x compound, wherein x is from 0 to 1, wherein A and B are different semiconductor elements, and wherein a value of x gradually varies as a function of at least one of: (i) a radial direction of the respective elongated nanostructure and (ii) an axial direction of the respective elongated nanostructure.

According to some embodiments of the invention each of at least a portion of the elongated nanostructure comprises an axially graded core, selected to constrain a unidirectional axial motion of charge carriers along the core.

According to some embodiments of the invention each of at least a portion of the elongated nanostructure comprises a plurality of concentric shells and an axially graded core, the axially graded core being selected to constrain a unidirectional axial motion of charge carriers along the core.

According to some embodiments of the invention the bandgap is within the visible range. According to some embodiments of the invention the bandgap is within the ultraviolet range. According to some embodiments of the invention the bandgap is within the infrared range.

According to some embodiments of the invention at least one of the elongated nanostructures is a single crystal heterostructure.

According to an aspect of some embodiments of the present invention there is provided a photovoltaic system comprising a plurality of photovoltaic cells.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions.

Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic illustration of a photovoltaic cell device according to some embodiments of the present invention;

FIG. 2A is a schematic illustration of a nanostructure having a sequence of p-type regions and n-type regions serially arranged along the axial direction, according to some embodiments of the present invention;

FIG. 2B is a is a schematic illustration of a nanostructure having a p-type region and an n-type region arranged generally concentrically in a core-shell relation, according to some embodiments of the present invention;

FIG. 3 is a schematic illustration showing, in a cross-sectional view, a nanostructure in embodiments of the invention in which the nanostructures includes a core having a chemical composition that is modulated along the axial direction to provide grading along the axial direction, and a plurality of concentric shells, each with a different chemical composition that provides grading along the radial direction;

FIG. 4A is a schematic illustration of a nanostructure having a silicon segment (Si) and a germanium segment (Ge), according to some embodiments of the present invention;

FIG. 4B is a schematic illustration of a nanostructure having a silicon segment (Si), a silicon germanium segment (SiₓGe₁₋ₓ), and a germanium segment (Ge), according to some embodiments of the present invention;

FIG. 5 is a schematic illustration of a cell device having several layers of active regions, according to some embodiments of the present invention;

FIGS. 6A-B are schematic illustrations of a photovoltaic system, according to some embodiments of the present invention;

FIG. 7 is a schematic illustration showing a process for forming a multi-shell nanostructure, according to some embodiments of the present invention;

FIGS. 8A-B are electron microscope images of an ordered rectangular array of silicon nanowires fabricated during experiments performed according to some embodiments of the present invention;

FIGS. 9A-B are electron microscope images of a side view (FIG. 9A) and a top view (FIG. 9B) of a core-shell nanostructure, fabricated during experiments performed according to some embodiments of the present invention;

FIG. 10 is an electron microscope image of a side view of a multi-shell nanostructure, fabricated during experiments performed according to some embodiments of the present invention; and

FIG. 11 is an electron microscope image of an ordered rectangular array of nanowires coated with nickel, fabricated during experiments performed according to some embodiments of the present invention.

### DESCRIPTION OF SPECIFIC EMBODIMENTS OF THE INVENTION

The present invention, in some embodiments thereof, relates to optoelectronics and, more particularly, but not exclusively, to a photovoltaic cell and method of fabricating the same.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

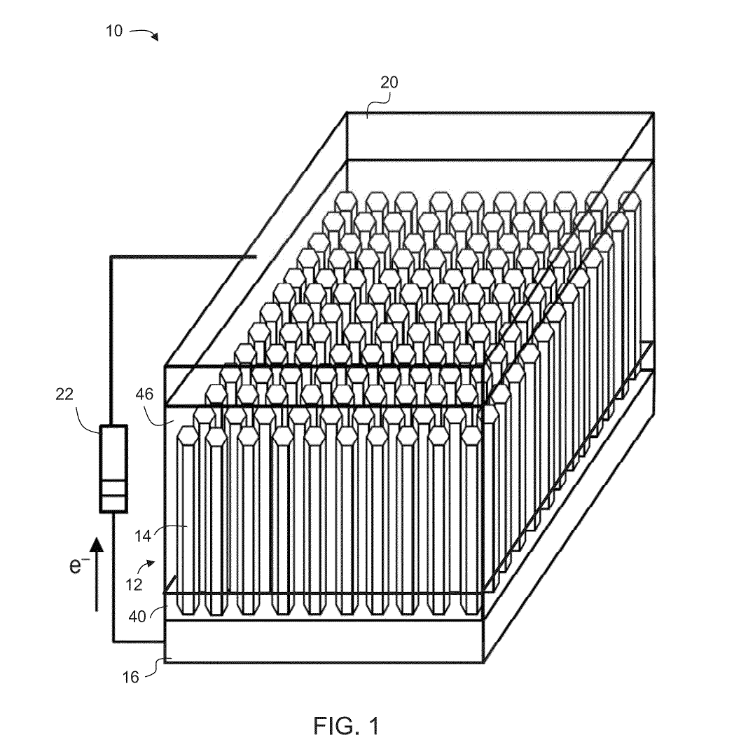

Referring now to the drawings, FIG. 1 illustrates a photovoltaic cell device 10 according to some embodiments of the present invention. Photovoltaic cell device 10 comprises an active region 12 having a plurality of spaced-apart elongated nanostructures 14 aligned generally vertically with respect to a substrate 16. The term “elongated nanostructure” generally refers to a three-dimensional body made of a solid substance, in which one of its dimensions is at least 2 times, or at least 10 times, or at least 50 times e.g., at least 100 times larger than any of the other two dimensions. The largest dimension of the elongated solid structure is referred to herein as the longitudinal dimension or the length of the nanostructure, and the other two dimensions are referred to herein as the transverse dimensions. The largest of the transverse dimensions is referred to herein as the diameter or width of the elongated nanostructure. The ratio between the length and the width of the nanostructure is known as the aspect ratio of the nanostructure.

In various exemplary embodiments of the invention the length of the elongated nanostructure is at least 100 nm, or at least 500 nm, or at least 1 μm, or at least 2 μm, or at least 3 μm, e.g., about 4 μm, or more. The width of the elongated nanostructure is preferably less than 1 μm. In various exemplary embodiments of the invention the width of the nanostructure is from about 5 nm to about 200 nm.

The elongated nanostructures of the present embodiments can be of any type known in the art, provided their diameter is in the sub-micron scale and that they are generally perpendicular with respect to the substrate. The nanostructures can be nanowires, in which case they can have a solid elongated structure (namely non-hollow structure), or they can be nanotubes, in which case they can have an elongated hollow structure. The nanostructures can also have a core-shell structure, as further detailed hereinbelow.

The term “generally vertically” refers to an angular relationship between a nanostructure and a plane engaged by a planar surface of a substrate. The nanostructure is said to be generally vertical with respect to the plane if the angle between the nanostructure and the normal to the plane is, on the average, less than 20°, more preferably less than 10°, more preferably less than 5°, more preferably, but not obligatorily, less than 2°.

Each of at least a portion of nanostructures 14 is preferably a heterostructure.

The term “heterostructure” as used herein refers to a structure in which materials having different compositions meet at interfaces. The different compositions forming a heterostructure can be different materials and/or different doping levels or types.

The different compositions can be distributed along the longitudinal direction of the elongated heterostructure, in which case the heterostructure is referred to as “axial heterostructure”, or they can be distributed along the radial direction (e.g., forming a core with one or more shells), in which case the heterostructure is referred to as a “radial heterostructure.” Both axial and radial heterostructures are contemplated in various embodiments of the invention.

An interface between two different compositions in a heterostructure can form a p-n junction, when the composition on one side of the interface includes a p-doping and the other the composition on the other side of the interface includes an n-doping. In various exemplary embodiments of the invention each of at least a portion of nanostructures 14 has at least one p-n junction characterized by a bandgap within the electromagnetic spectrum.

In some embodiments of the present invention at least one of the p-n junctions is characterized by a bandgap within the infrared range, e.g., the mid and/or far infrared range, in some embodiments of the present invention at least one of the p-n junctions is characterized by a bandgap within the visible range, and in some embodiments of the present invention at least one of the p-n junctions is characterized by a bandgap within the ultraviolet range.

The p-n junction(s) are formed between p-type and n-type region of nanostructures 14. This can be embodied in more than one way.

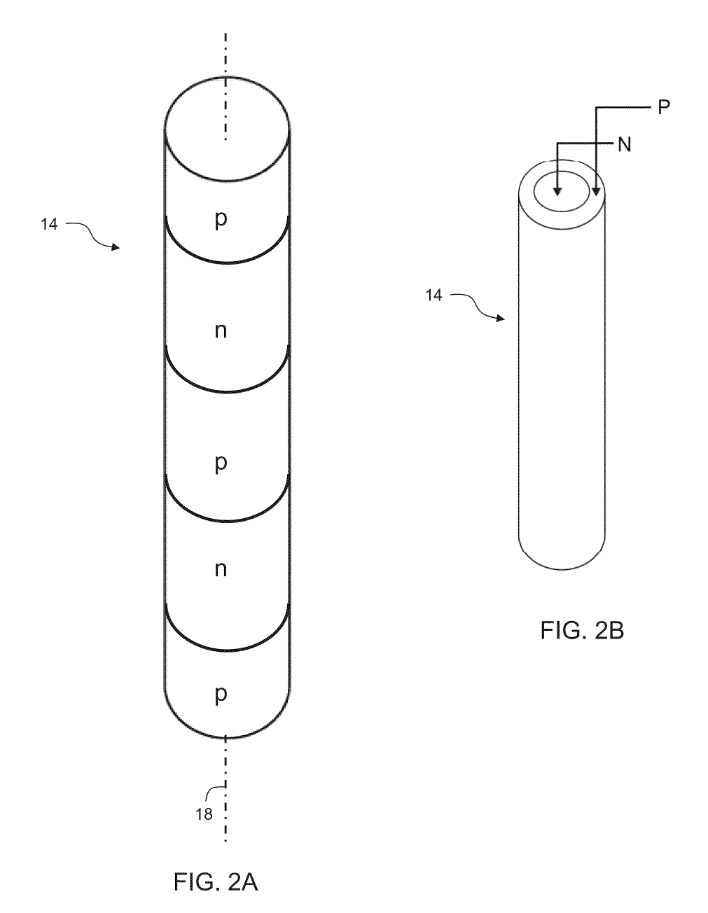

In some embodiments, illustrated in FIG. 2A, the p-type and n-type region are arranged serially along an axial direction 18 of a respective elongated nanostructure. Shown in FIG. 2A, is a sequence (e.g., an alternating sequence) of p-type regions and n-type regions serially arranged along axial direction 18. However, this need not necessarily be the case, since, for some applications, it may not be necessary for the nanostructure to have a sequence of p-type regions and n-type region. For example, in some embodiments of the present invention nanostructure 14 comprises a single p-type region adjacent to a single n-type region, thus forming a single p-n junction.

In these embodiments, electron-hole pairs are generated throughout the device upon absorption of photons whose energies are equal to or greater than the band-gap of the nanostructure (e.g., 1.12 eV for single-crystal silicon). Carrier generation and separation are most efficient within the depletion region due to the built-in field established across the p-n junction. Once swept in the direction of the electric field, the photo-generated holes move through the p-type region and the photo-generated electrons move through the n-type regions. The photo-generated holes and electrons are then collected as a photocurrent by electrodes or metal collector contacts at opposite sides of the nanostructure (not shown, see, e.g., FIG. 1). In this axial configuration, the p-type and n-type regions are optionally and preferably short since their main purpose is to provide contact to the p-n junction embedded within the nanowire. Thus, active region 12 can be kept very thin.

In some embodiments of the present invention, illustrated in FIG. 2B, nanostructure 14 comprises a p-type region and an n-type region arranged generally concentrically in a core-shell relation. FIG. 2B shows a single n-type core and a single p-type shell. However, this need not necessarily be the case, since, for some applications, nanostructure 14 can comprise a p-type core and an n-type shell. Further, nanostructure 14 can be a multi-shell structure (not shown) having a plurality of p-type regions and n-type regions arranged, for example, in an alternating manner, to form a plurality of generally concentric shells. In embodiments in which the p-type region and an n-type region are arranged generally concentrically, the p-n junction optionally and preferably extends along the whole length of nanostructure 14. Therefore, the carrier separation takes place over a surface area defined by the length of the nanostructure and inner the perimeter of the respective shell. The carrier collection distance is smaller or comparable to the minority carrier diffusion length, so that the photo-generated charge carriers (electron and holes) can reach the p-n junction with higher efficiency with reduced bulk recombination.

The n-type and p-type regions of nanostructure 14 are preferably made of a semiconductor substance doped by a dopant selected to effect the conductivity type of the region. A p-type region can include an intrinsic semiconductor doped with a dopant that creates deficiencies of valence electrons (i.e., holes), and an n-type region can include an intrinsic semiconductor doped with a dopant that contributes free electrons. In a region containing a group IV semiconductor (e.g., silicon, germanium), examples of p-type dopants, include, but are not limited to, boron, aluminum, gallium and indium, and examples of n-type dopants include, but are not limited to, antimony, arsenic and phosphorous.

The intrinsic semiconductor materials in two adjacent n-type and p-type regions of nanostructure 14 have a crystallinity mismatch of less than 6% or less than 5.5% or less than 5% or less than 4.5%.

The phrase “crystallinity mismatch”, also referred to as “lattice mismatch”, is defined as the difference between the lattice constants of the two intrinsic semiconductor materials expressed as a percentage of one of the lattice constants (e.g., the larger lattice constant).

The advantage of having low crystallinity mismatch between adjacent regions is that it provides a single-crystal elongated heterostructure of nanometric size. An “elongated heterostructure of nanometric size” means a heterostructure having the dimensions of a nanostructure as defined above.

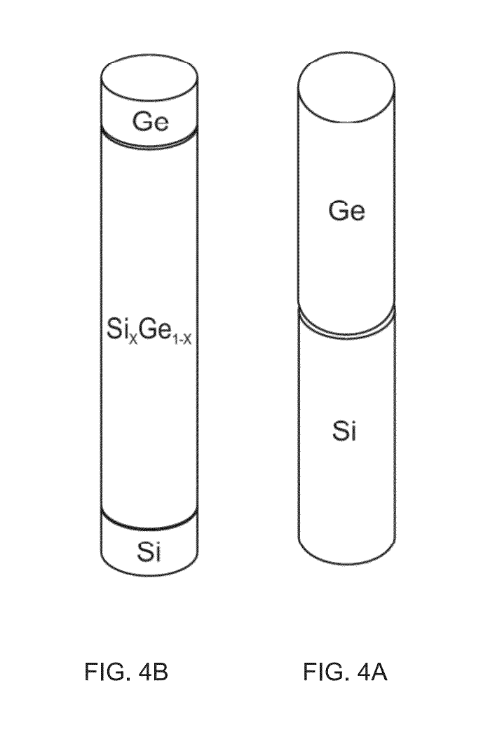

Exemplary semiconductor materials suitable for the present embodiments include, but are not limited to, silicon (Si), germanium (Ge), zinc oxide (ZnO), zinc sulfide (ZnS), gallium nitride (GaN), silver (Ag), gold (Au), and a binary, ternary or quaternary element selected from the group consisting of a Group II-VI element, a Group III-V element, and a Group IV element. Additional examples including, without limitation, titanium (Ti), bismuth (Bi), tellurium (Te), lead (Pb) silicon carbide (SiC), gallium arsenide (GaAs), gallium phosphide (GaP), indium phosphide (InP), indium arsenide (InAs), aluminum nitride (AlN), indium oxide (InO), indium tin oxide (ITO) and cadmium sulfide (CdS). According to some embodiments of the invention, at least one intrinsic semiconductor materials comprises silicon, and at least one intrinsic semiconductor materials comprises germanium. The silicon-germanium couple has a crystallinity mismatch of 4.2%. A representative example of a nanostructure 14 having a silicon segment (Si) and a germanium segment (Ge) forming a p-n junction therebetween is illustrated in FIG. 4A.

In various exemplary embodiments of the invention at least a few of the p-type regions and n-type regions are graded thereamongst.

As used herein “at least a few” means at least 20%, or at least 30%, or at least 40%, or at least 50%, or at least 60%, or at least 70%, or and preferably at least 80%, or at least 90%, or at least 95%, or at least 98%, or 100%.

The p-type regions and n-type regions are graded in the sense that the difference in chemical composition at each junction gradually changes as one move from one junction to the other.

For example, at least a few of the p-type regions and n-type regions can be made of a AₓB₁₋ₓ compound, where x is from 0 to 1, and where A and B represent different semiconductor elements (e.g., A can be silicon, and B can be germanium). In these embodiments, the grading is optionally and preferably characterized by a gradually varying value of x as a function of the radial and/or axial direction of the respective elongated nanostructure.

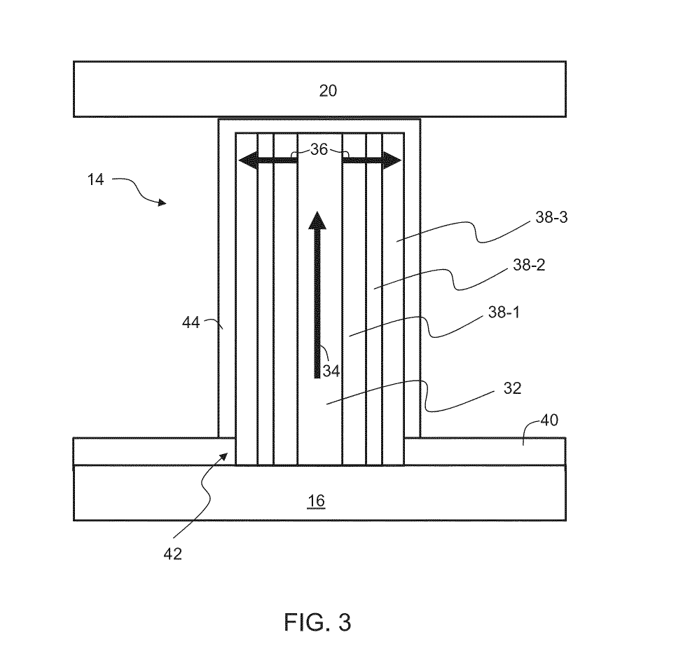

The present embodiments contemplate a configuration in which the grading is employed both axially and radially. For example, with reference to FIG. 3, nanostructure 14 can include a core 32 having a chemical composition that is modulated along the axial direction to provide grading along the axial direction, and a plurality of concentric shells 38-1, 38-2, 38-3, etc., each with a different chemical composition that provides grading along the radial direction. In FIG. 3, the grading along the axial direction is represented by arrow 34, and the grading along the radial direction is represented by arrows 36. The modulation of chemical composition along the axial direction can be effected, for example, by a gradient of dopant concentration along the axial direction.

A representative example of a nanostructure 14 having a silicon segment (Si) and a silicon germanium segment (SiₓGe₁₋ₓ) and a germanium segment (Ge), is illustrated in FIG. 4B. In this configuration, two p-n junctions are formed: a first p-n junction between the Si segment and the SiₓGe₁₋ₓ segment, and a second p-n junction between the SiₓGe₁₋ₓ segment and the Ge segment.

Nanostructures 14 are optionally and preferably grown vertically on substrate 16, which is preferably electrically conductive and can therefore serve as a bottom electrode of device 10. Substrate 16 can be made of any conductive material, including, without limitation, a silicon wafer (e.g., a highly doped silicon wafer) and an electrically conductive plastic.

Substrate 16 is preferably coated, at least partially, by an electrically insulating layer 40 at a base level of nanostructures 14. Layer 40 coats substrate 16 or part thereof such that the base 42 of nanostructure 14 is buried in layer 40. In embodiments in which nanostructure comprises a core and one or more shells, layer 40 can cover the base part of the core and shells, as illustrated in FIG. 3. Alternatively, nanostructure 14 can have a core that is longer than the shells at the base part of nanostructures such that layer 40 covers only the core 34, leaving the shells unburied.

Aside from the shells 38 of nanostructure 14 (in embodiments in which shells 38 are employed), nanostructure 14 is coated by a conductive layer 44, optionally and preferably throughout its unburied length. Layer 44, together with substrate 16, serve as a pair of charge carrier collectors for collecting charge carriers generated in one or more of the p-n junctions of nanostructure 14 responsively to light incident on nanostructure 14.

Layer 44 is preferably transparent to light at wavelengths corresponding to one or more of, preferably all, the bandgaps of nanostructure 14. Layer 44 optionally and preferably has a low crystallinity mismatch (e.g., less than 3% or less than 2% or less than 1%) with the shell or core on which it is deposited. Layer 44 can comprise, or be, a silicide, preferably a metal silicide such as, but not limited to, nickel silicide, cobalt silicide, palladium silicide, platinum silicide, iron silicide, titanium silicide and tungsten silicide. In various exemplary embodiments of the invention the resistivity of layer 44 is at most 10⁻³ Ωcm² or at most 10⁻⁴ Ωcm². In some embodiments of the present invention, layer 44 is nickel silicide, e.g., NiSi. The thickness of layer 44 is optionally and preferably from about 5 nm to about 10 nm.

In various exemplary embodiments of the invention the spaces between the conductive layers of the nanostructures are filled with an electrically insulating substance 46, such as, but not limited to, silicone oxide or any other electrically insulating material that is transparent to the transparent to light at wavelengths corresponding to one or more of, preferably all, the bandgaps of nanostructure 14. Filling 46 serves as a mechanical support for the nanostructures.

Device 10 can further comprise an electronic circuitry 22 configured for extracting from active region 12 electrical current and/or voltage generated responsively to light incident on active region 12. Electrical contact between electronic circuitry 22 and active region 12 can be established via substrate 16 and a top contact layer 20 covering active region 12, and being in electrical contact with the conductive layer that coats the nanostructures. Top contact layer 20 can be made of any conductive material that is transparent to light at wavelengths that match the characteristics bandgaps of nanostructures 14. For example, top layer 20 can comprise ITO, be provided as an ITO grid, or the like.

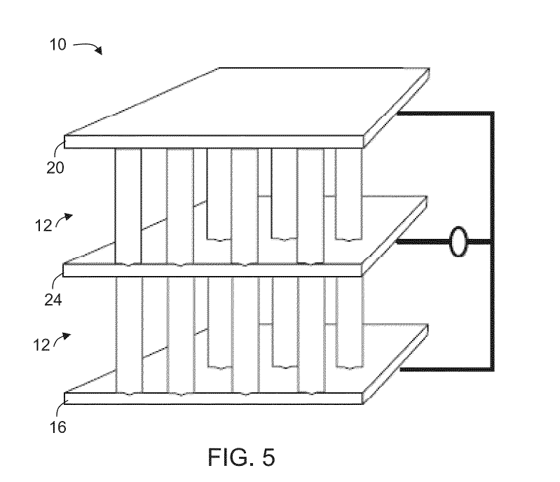

Device 10 can include several layers of active regions. A representative example of this embodiment is illustrated in FIG. 5. Shown in FIG. 5 is a stack of two active region layers 12 with an intermediate electrode 24 between the active region layers. The present embodiments contemplate any number of active region layers.

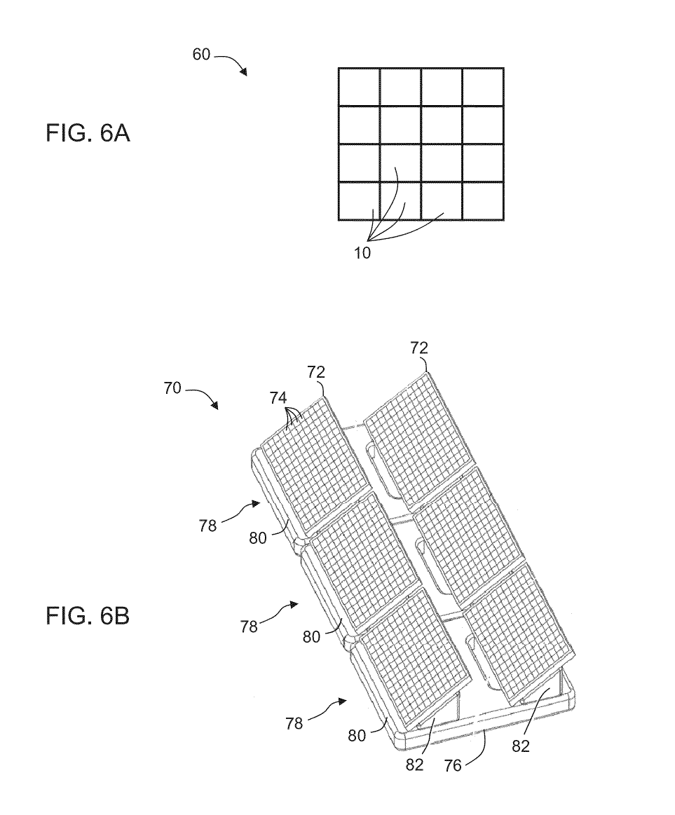

FIGS. 6A-B are schematic illustrations of a photovoltaic system, according to some embodiments of the present invention. The photovoltaic system of the present embodiments comprises a plurality of photovoltaic cells, each cell can be embodied as cell device 10. The photovoltaic cells can be arranged in any geometrical configuration, and any number of photovoltaic cells can be included in the photovoltaic system. FIG. 6A shows a system 60 in which the photovoltaic cells are arranged gridwise over a rectangular grid. FIG. 6B shows a system 70 which comprises one or more solar panels 72, where each panel comprises a plurality of photovoltaic systems 74. An individual system 74 can include a single photovoltaic cell, such as, but not limited to, cell device 10, or it can include a plurality of photovoltaic cells, such as, but not limited to, system 60. System 70 can comprise a supporting structure 76 on which panels 72 are mounted. Structure 76 can comprise a floating support 78 constituting an independent module to be associated to other like modules. The floating module can include a floating base element 80 and one or more support elements 82 for the photovoltaic panels 72.

Following is a description of a method suitable for fabricating an active region according to some embodiments of the present invention. The method is particularly useful for fabricating region 12 of device 10.

The present inventors have devised and successfully practiced a process for reproducibly producing elongated nanostructures having defined diameter, morphology, shape and chemical composition. Using this process, robust single-crystalline elongated nanostructures, with well-controlled and uniform diameter, taper angle and chemical composition can be prepared.

The synthetic approach of the present embodiments enables independent control of diameter, shell thickness, shape, taper angle, crystallinity and chemical/electrical composition of the obtained nanostructures. In accordance with some embodiments of the present invention, diameter and shell thickness of nearly any size can be obtained. This is advantageous over the traditional techniques since it allows to achieve high quality electronic materials and to tailor the properties of the nanostructures to better-fit the active region of the device.

The nanostructures can be tubular, conical or have the shape of a funnel having a generally conical or conical segment and a generally cylindrical or cylindrical segment. Selective doping of core and shells is also contemplated. For example, in-situ doping with different concentrations of boron and phosphine, each applied to a different shell can provide p-n junctions along the radial direction. Alloy multi-shell nanostructures can also be prepared.

Herein throughout, wherever a nanostructure is described, a plurality (collection) of such nanostructures is also contemplated. In some embodiments, at least a few of the nanostructures in the collection have the characteristics described for the nanostructure.

The method according to some embodiments of the present invention is effected such that at least one of a shape, diameter, shell thickness and/or chemical composition of the produced nanostructures is reproducibly controlled. In some embodiments, the method is effected such that each of the shape, diameter, shell thickness and/or chemical composition of the produced nanostructures is independently reproducibly controlled. The method described herein can therefore be used, for example, for mass production of nanostructures with uniform, yet versatile, characteristics.

It is to be understood that, unless otherwise defined, the operations described hereinbelow can be executed either contemporaneously or sequentially in many combinations or orders of execution. For example, two or more operations, appearing in the following description in a particular order, can be executed in a different order (e.g., a reverse order) or substantially contemporaneously. Additionally, several operations described below are optional and may not be executed.

The method of the present embodiments is effected by growing a nanowire made of a crystalline, semiconductor substance. The nanowire serves as a core of the nanostructures. In embodiments in which an axially graded core is desired, the growth is executed in the presence of a vapor phase that varies with time, such that at each time-interval, the chemical composition of the grown a core segment differs from the chemical composition of the core segment that was grown at a former time-interval. The method proceeds by epitaxially growing, onto the nanowire, a layer of another semiconductor substance that has a low (e.g., 4.5% or less) crystallinity mismatch with the core. The epitaxially grown layer serves as a shell of the nanostructure. The method can proceed by repeating (one or more times) the epitaxially growth onto the shell, optionally and preferably with a different semiconductor substance, thereby providing a multi-shell nanostructure.

Selecting a couple of a semiconductor substances for forming the nanostructure with low crystallinity mismatch allows the epitaxial growth of a layer of single-crystalline semiconductor substance onto the core or inner shell(s), while circumventing the need to perform further procedures so as to achieve a desired crystallinity.

The semiconductor substance of the core and any of the shells can include one or more of the semiconductor materials described above.

According to some embodiments of the invention, the nanowire is grown on a substrate that has sufficient electrical conductance, so as to allow it to serve as a bottom electrode, as further detailed hereinabove.

According to some embodiments of the invention, growing the nanowire is effected in the presence of a catalyst that is optionally and preferably in the form of nanoparticle. The catalyst nanoparticle is preferably made of a metal catalyst material. The metal catalyst material is selected so as to catalyze nanowire growth, for example, via the vapor-liquid-solid (VLS) mechanism.

In VLS, a catalyst comprising a metal or metal alloy is used to direct nanowire growth. The catalyst is initially dispersed across the surface of a substrate as suitably-sized nanoparticles which transform to the liquid alloy phase upon heating and supplying of semiconductor material. The liquid alloy nanoparticles absorb atoms from the vapor phase, facilitating the nucleation of crystal seeds at the liquid-substrate interface from which nanowire growth can occur. The material constituting the growing nanowire and the nanoparticle form a liquid-phase binary alloy drop whose interface with the growing wire represents the nanowire growth front. Under steady-state growth conditions, adsorption on the drop surface maintains a concentration gradient of the nanowire component of the liquid binary alloy, which is counteracted by a diffusion current through the drop. This liquid phase transport, in turn, causes a small super-saturation driving the incorporation of new material at the drop-nanowire interface to continually extend the wire.

The type of metal catalyst material typically depends on the nanostructure material. Generally, any metal able to form an alloy with the desired semiconductor material, but does not form a more stable compound than with the elements of the desired semiconductor material may be used as the catalyst material. Representative examples of metal catalyst materials suitable for the present embodiments include, without limitation, gold, silver, copper, zinc, cadmium, iron, nickel and cobalt. Any other material that is recognized as useful as a catalyst for nanostructure growth by the selected technique is also contemplated.

Accordingly, in some embodiments, the method is effected by depositing onto the substrate nanoparticles that are suitable for catalyzing the nanowire growth. Thus, in some embodiments, the substrate has nanoparticles dispersed thereon, in some embodiments, the nanoparticles are deposited on the substrate from a colloidal solution.

In some embodiments of the present invention the nanoparticles are deposited to form clusters of nanoparticles, referred to herein as nanoclusters. The size of the nanoclusters determines the initial diameter of the core. The initial diameter can, in some embodiments of the present invention, be further manipulated so as to obtain nanostructures with non-uniform core diameter along its length.

In some embodiments, the nanoclusters have a diameter that ranges from 5 nm to 50 nm. In some embodiments, the nanoclusters have a diameter of about 20 nm.

In some embodiments, the VLS mechanism is coupled with a chemical vapor deposition, so as to effect nanowire growth. In some embodiments, nanowire growth is effected in an ultra high vacuum chemical vapor deposition (UHV-CVD) system.

The conditions used to effect nanowire growth can be manipulated so as to affect the shape of the resulting nanostructure.

According to some embodiments of the invention, growing the nanowire comprises a chemical vapor deposition (CVD) performed at conditions that affect axial growth of the nanowire.

In embodiments where the semiconductor substance is germanium, the CVD is performed at a temperature of from 270° C. to 290° C. In some embodiments, CVD is performed at 280° C. It is noted that the CVD temperature used for growing the nanowire may affect the crystallinity of the obtained nanostructures, such that, for example, at lower or higher temperatures, an amorphous morphology is obtained, requiring a further procedure of annealing. For example, Lauhon et al., Nature, Vol. 420, 2002, have prepared Ge—Si multishell nanowires by growing Ge core nanowire at 380° C., to affect radial growth and have obtained an amorphous silicon shell.

In some embodiments, for any semiconductor substance used, CVD is performed at a temperature that results in axial growth of the nanowire, and in any event, that does not result in radial growth.

According to some embodiments of the invention, the CVD is performed using germane (GeH₄ as a precursor), in a hydrogen carrier.

The amount of germanium can be manipulated by the concentration of the precursor in the carrier, the carrier flow and/or the pressure at which the procedure is effected.

In some embodiments, CVD is performed using 10% germane in 200 sccm H₂ and 400 Torr.

According to some embodiments of the invention, growing the germanium nanowire further comprises, prior to the CVD, a preliminary CVD, in order to effect nucleation. In some embodiments, this procedure is performed at a temperature of 315° C. Other temperatures in the ranges of ±20° C. can also be used.

According to some embodiments of the invention, growing the nanowire comprises a CVD performed at conditions that affect conformal growth of the nanowire.

In some embodiments, particularly in cases where the semiconductor substance is germanium, the CVD is performed at a temperature higher than 300° C., so as affect conformal growth of the nanowire.

According to some embodiments of the invention, the CVD is performed using 10% germane in 200 sccm H₂ and 400 Torr. Other parameters are also contemplated, as discussed herein.

According to some embodiments of the invention, conformal growing the germanium nanowire further comprises a preliminary CVD, performed at a temperature of 315° C., as described herein, to affect nucleation.

According to some embodiments of the invention, performing the CVD as described in these embodiments, such that a conformal growth of the nanowire is effected, results in a generally conical nanostructure.

According to some embodiments of the invention, a taper angle of the conical nanostructures ranges from 1° to 10°. According to some embodiments of the invention, a taper angle of the conical nanostructures ranges from 1.5° to 5°. The taper angle of conical nanostructures described herein can be manipulated and finely controlled by manipulating the conditions at which CVD is performed.

According to some embodiments of the invention, growing the nanowire template comprises a first CVD performed at conditions that affect conformal growth of the nanowire, followed by a second CVD performed at conditions that affect axial growth of the nanowire. Growing the nanowire under such conditions results in nanostructures which are generally funnel-like nanostructures.

According to some embodiments of the invention, the semiconductor substance is germanium and the first CVD is performed so as to affect conformal growing of the nanostructure, as described herein. Similarly to the growing of conical nanowires described herein, the taper angle of the conical part of the “funnel-like” nanostructures described herein can be finely-controlled.

Once a nanowire with defined shape and crystallinity is obtained, a layer of the additional semiconductor substance of choice is grown on the nanowire.

By “epitaxial growth” or “epitaxially growing” it is meant that a crystalline layer of one substance (herein the inorganic substance) is grown on top of an existing single-crystalline base (herein the nanowire made of the semiconductor substance) in such a way that its crystalline orientation is the same as that of the base.

Vapor phase epitaxy is one of the most common processes for epitaxial layer growth. Any of the known techniques for vapor phase epitaxy can be used in these embodiments. In some embodiments of the invention, epitaxially growing the layer of the inorganic substance is effected by CVD.

In some embodiments of the invention, the second substance is silicon and the CVD is performed using silane in a mixture of H₂ and Ar.

According to some embodiments of the invention, the CVD is performed using 5 sccm silane in a mixture of 10 sccm H₂ and 5 sccm Ar, at 1 Torr.

According to some embodiments of the invention, the CVD is performed at a temperature that ranges from 440° C. to 460° C. In some embodiments, the CVD is performed at a temperature of 450° C.

The shell thickness of the obtained nanostructures can be finely controlled by controlling the duration time of growing the shell.

Thus, according to some embodiments of the invention, the CVD is performed during a time period that ranges from 10 minutes to 200 minutes. According to some embodiments of the invention, a corresponding thickness of the shell ranges from about 1 nm to about 50 nm.

According to some embodiments of the invention, the CVD is performed during a time period that ranges from about 20 minutes to about 120 minutes. According to some embodiments of the invention, a corresponding thickness of the shell ranges from about 5 nm to about 20 nm.

The method of the present embodiments can control the diameter of the formed core. The method of the present embodiments allows to finely control the diameter of the nanowire substantially without affecting the crystallinity.

Hence, according to some embodiments of the invention, the method further comprises, prior to the epitaxially growing the layer of the inorganic substance, reducing a diameter of the nanowire. In some embodiments, reducing the diameter is performed without affecting a crystallinity of the nanowire.

According to some embodiments of the invention, reducing the diameter is effected via thermal oxidation, etching or both. For example, when the semiconductor substance is germanium, reducing the diameter can be effected by thermal oxidation, followed by etching of the formed oxide layer.

A representative process for reducing the diameter, which is not to be considered as limiting, is as follows:

contacting the nanowire with oxygen, to thereby convert an external portion of the germanium to germanium oxide; and

etching the external portion of the germanium oxide.

According to some embodiments of the invention, the contacting of the nanowire with oxygen is effected at 250° C. and 1 Torr.

According to some embodiments of the invention, the contacting of the nanowire with oxygen is effected during 0.5-5 hours.

According to some embodiments of the invention, the contacting is effected during 1-3 hours.

According to some embodiments of the invention, the method further comprising, prior to the contacting, removing a native germanium oxide layer from the surface of the nanowire.

Thermal oxidation followed by etching, or etching alone, can be utilized for forming nanowires with reduced diameter also for other semiconductor substances, as long as the procedure is performed at conditions that do not affect the crystallinity of the formed nanowire.

Alternatively, the method is effected by increasing the diameter of the formed nanowire, prior to epitaxially growing the shell. This can be performed by depositing an external layer of the semiconductor substance onto the nanowire.

According to some embodiments of the invention, the semiconductor substance is germanium and depositing the external layer is effected by CVD, at conditions that affect radial growth of the external layer. According to some embodiments, the selected conditions do not affect the crystallinity of the formed nanowire.

According to some embodiments of the invention, the chemical composition of the nanostructures is manipulated by epitaxially growing the shell in a presence of an additional substance, to thereby obtain nanostructures which comprise a mixture of substances.

Accordingly, a shell comprising a mixture of two or more substances is formed.

In some embodiments of the invention, the additional substance is a semiconductor substance, utilized for improving or controlling conductivity of the formed shell. In some embodiments, the additional substance is a metal, such that the resulting shell is formed from alloyed substance. In some embodiments, the additional substance is a p-dopant or an n-dopant, added so as to affect electrical conductivity of the formed shell.

According to some embodiments of the invention, an atomic ratio between the semiconductor substance and the additional substance ranges from 100:1 to 10,000:1, or from 100:1 to 1,000:1.

According to some embodiments of the invention, the method further comprising, subsequent to the epitaxial growth, chemically modifying at least a portion of a surface of the epitaxially grown layer. The modification can be effected, for example, by covalently attaching a chemical substance to a functional group on a surface of the layer of the inorganic substance. In some embodiments of the invention, the modifying affects the hydrophillicity or hydrophobicity of the surface. A person skilled in the art could readily determine the chemical modification of choice and the chemical substances utilized to affect the desired surface modification.

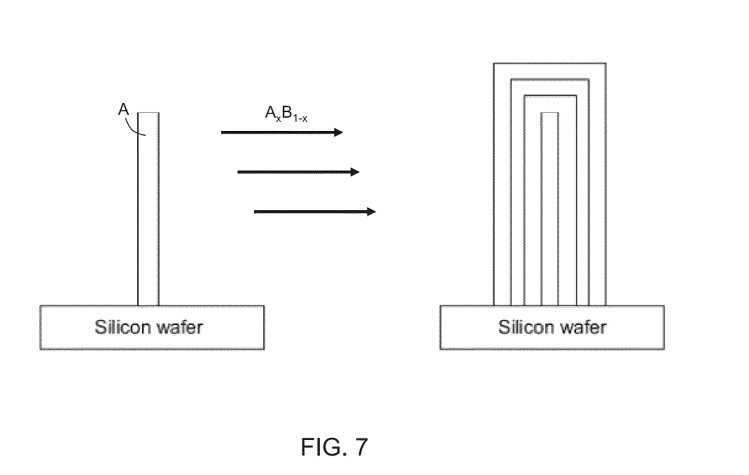

FIG. 7 is a schematic illustration of selected operations described above, in embodiments in which the core is a semiconductor element A, and the shells are graded according to AₓB₁₋ₓ, where x is monotonically decreased outwardly. For example x can be 0.66 for the shell grown on the core, 0.33 for the second shell and 0 for the outermost shell.

Once the core, and optionally and preferably also the shells of the nanostructures are formed, an electrically insulating layer (e.g., layer 40, see FIGS. 1 and 3) is applied such that the base of the nanostructure is buried therein. This can be done, for example, by conformal evaporation of an electrically insulating substance, such as, but not limited to, silicon oxide or silicon nitride. The thickness of the electrically insulating layer depends on the dielectric constant of the electrically insulating substance, and is selected to prevent substantive leakage of charge carrier therethrough. A typical thickness of this layer is from about 5 nm to about 200 nm, or from about 5 nm to about 100 nm.

Following the application of electrically insulating layer at the base level of the nanostructures, an electrically conductive layer (e.g., layer 44) is deposited on each of at least a portion of the nanostructures. This layer preferably covers each nanostructure throughout its unburied length, as well as at the tip that is farther from the base. An electrically conductive coating layer can be applied, according to some embodiments of the present invention by CVD. The precursor for the CVD is optionally and preferably a volatile organo-metal substance. For example, for a nickel-based electrically conductive coating layer, the precursor can include a volatile complex of nickel, such as, but not limited to, a cyclopentadienyl nickel.

Following the CVD process, the deposited substance is optionally and preferably subjected to an annealing process to allow at least partial diffusion of the deposited substance into the outermost shell of the nanostructures. For example, when the outer shell comprises silicon and the deposited substance comprises metal (e.g., nickel), the annealing process results in formation of a metal silicide coating layer (e.g., a nickel silicide coating layer). The annealing is optionally and preferably executed by a technique known as Rapid Thermal Processing (RTP), in which the nanostructures and deposited coating substance are subjected to a heat spike. Once the silicide layer is formed, residual deposited substance is preferably removed, as known in the art.

The method of the present embodiments optionally and preferably provides a mechanical support for the grown nanostructures. Ion these embodiments, the spaces between the conductive layers of the nanostructures are filled with an electrically insulating substance, such as, but not limited to, silicone oxide or any other electrically insulating material that is transparent to the transparent to light at wavelengths corresponding to one or more of, preferably all, the bandgaps of nanostructure.

In various exemplary embodiments of the invention a top contact layer (e.g., layer 20, see FIGS. 1 and 3), is applied, horizontally or generally horizontally, on top of the nanostructures such as to establish contact with the conductive coating layer of the nanostructure. The top contact layer can be made of any conductive material that is transparent to light at wavelengths that match the characteristics bandgaps of the nanostructures. For example, the top contact layer can comprise ITO, be provided as an ITO grid, or the like. A typical process for applying the top contact layer is, without limitation, spin coating.

As used herein the term “about” refers to ±10%.

The word “exemplary” is used herein to mean “serving as an example, instance or illustration.” Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments.” Any particular embodiment of the invention may include a plurality of “optional” features unless such features conflict.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

In accordance with some embodiments of the present invention described above, the present inventors successfully fabricated large vertically aligned nanowire arrays and multi-shell graded nanowires.

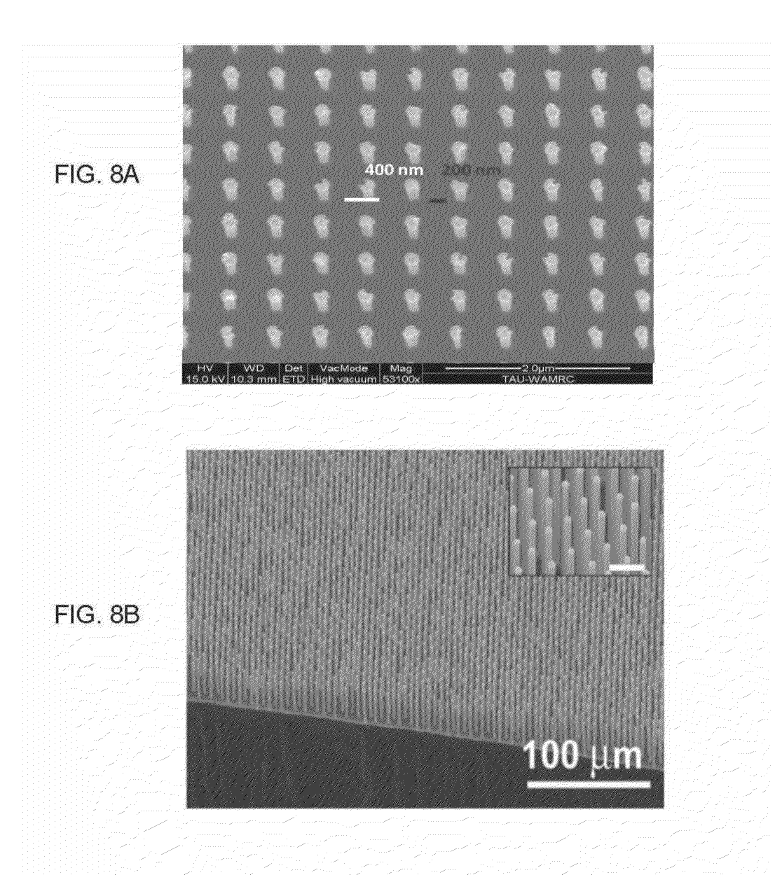

FIGS. 8A-B are electron microscope images of an ordered rectangular array of silicon nanowires grown vertically on a silicon wafer. The diameter of each nanowire is about 200 nm and the distance between nearest neighbors' nanowires is about 400 nm.

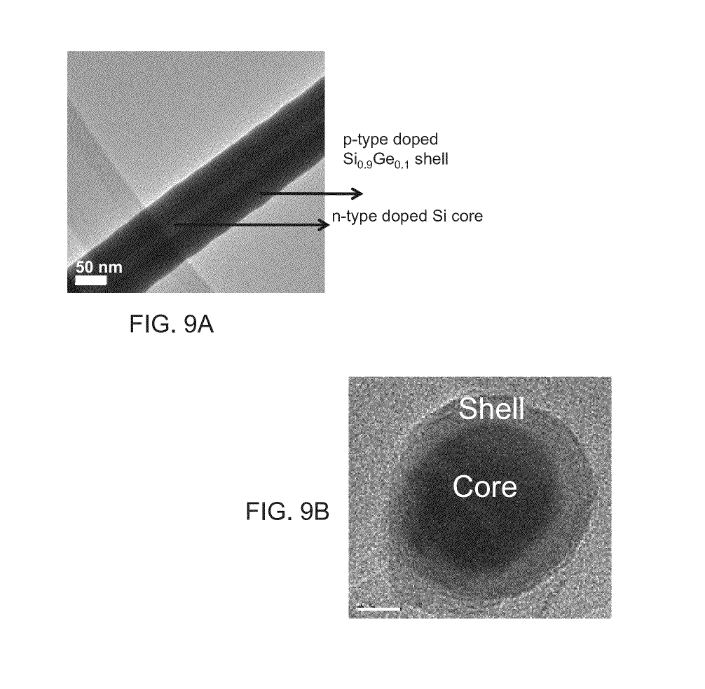

FIGS. 9A-B are electron microscope images of a side view (FIG. 9A) and a top view (FIG. 9B) of a core-shell nanostructure. The core is an n-type doped silicon, and the shell is a p-type doped SiₓGe₁₋ₓ, with x=0.9.

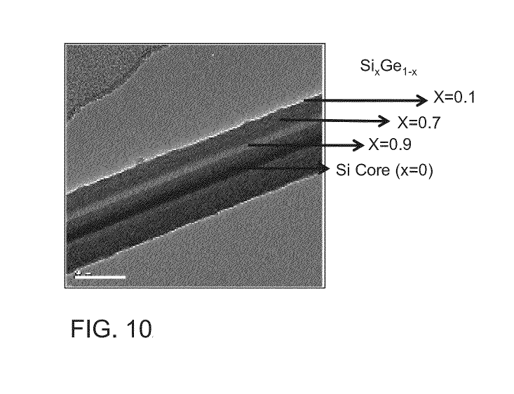

FIG. 10 is an electron microscope image of a side view of a multi-shell nanostructure. The core is silicon, and the shells are SiₓGe₁₋ₓ, with x=0.9, 0.7 and 0.1, decreasing outwardly.

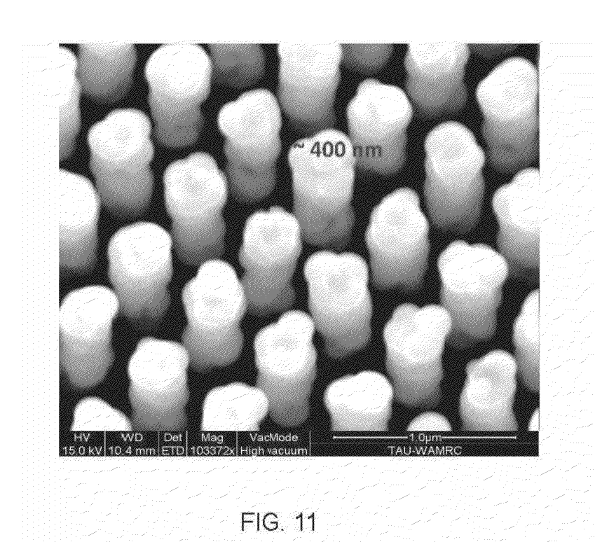

FIG. 11 is an electron microscope images of an ordered rectangular array of silicone nanowires coated with nickel silicide. The diameter of each nanowire is about 400 nm and the distance between nearest-neighbor nanowires is also about 400 nm.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A photovoltaic cell, comprising:
an active region having a plurality of spaced-apart elongated nanostructures aligned vertically with respect to an electrically conductive substrate, wherein each elongated nanostructure has at least one p-n junction characterized by a bandgap within the electromagnetic spectrum, and is coated by an electrically conductive layer being electrically isolated from said substrate; and
electronic circuitry for extracting from said substrate and said conductive layer electrical current and/or voltage generated responsively to light incident on said active region.

2. The photovoltaic cell of claim 1, wherein said electrically conductive layer comprises a metal.

3. The photovoltaic cell of claim 1, wherein said electrically conductive layer comprises a metal silicide selected from the list consisting of nickel silicide, cobalt silicide, palladium silicide, platinum silicide, iron silicide, titanium silicide and tungsten silicide.

4-5. (canceled)

6. The photovoltaic cell according to claim 1, wherein said at least one p-n junction comprises a plurality of p-n junctions.

7. The photovoltaic cell according to claim 1, wherein said at least one p-n junction comprises a p-type region and an n-type region arranged generally concentrically in a core-shell relation.

8. The photovoltaic cell of claim 7, wherein said at least one p-n junction comprises a plurality of p-type regions and n-type regions arranged to form a plurality of generally concentric shells.

9. The photovoltaic cell according to claim 7, wherein at least a few of said p-type regions and n-type regions are graded thereamongst.

10. The photovoltaic cell according to claim 9, wherein at least a few of said p-type regions and n-type regions are made of a AₓB₁₋ₓ compound, wherein x is from 0 to 1, wherein A and B are different semiconductor elements, and wherein said grading is characterized by a gradually varying value of x as a function of at least one of: (i) a radial direction of said respective elongated nanostructure and (ii) an axial direction of said respective elongated nanostructure.

11. The photovoltaic cell according to claim 1, wherein said at least one p-n junction comprises a plurality of p-type regions and n-type regions arranged to form a plurality of generally concentric shells, wherein at least a few of said p-type regions and n-type regions are made of a AₓB₁₋ₓ compound, wherein x is from 0 to 1, wherein A and B are different semiconductor elements, and a value of x gradually varies as a function of at least one of: (i) a radial direction of said respective elongated nanostructure and (ii) an axial direction of said respective elongated nanostructure.

12. The photovoltaic cell according to claim 10, wherein A is silicon and B is germanium.

13. The photovoltaic cell according to claim 2, wherein each of at least a portion of said elongated nanostructure comprises an axially graded core, selected to constrain a unidirectional axial motion of charge carriers along said core.

14. The photovoltaic cell according to claim 1, wherein each of at least a portion of said elongated nanostructure comprises a plurality of concentric shells and an axially graded core, said axially graded core being selected to constrain a unidirectional axial motion of charge carriers along said core.

15. The photovoltaic cell according to claim 1, wherein said bandgap is within a range selected from the group consisting of the visible range, the ultraviolet range and the infrared range.

16-17. (canceled)

18. The photovoltaic cell according to claim 1, wherein at least one of said elongated nanostructures is a single crystal heterostructure.

19. A photovoltaic system comprising a plurality of photovoltaic cells, each being according to claim 1.

20. A method of harvesting solar energy, comprising:
exposing an active region of a photovoltaic cell to solar radiation, said active region having a plurality of spaced-apart elongated nanostructures aligned vertically with respect to an electrically conductive substrate, wherein each elongated nanostructure has at least one p-n junction characterized by a bandgap within the electromagnetic spectrum, and is coated by an electrically conductive layer being electrically isolated from said substrate; and
extracting from said active region electrical current and/or voltage responsively to said solar radiation.

21. The method of claim 20, wherein said electrically conductive layer comprises a metal.

22. The method according to claim 20, wherein said at least one p-n junction comprises a plurality of p-n junctions.

23. The method according to claim 20, wherein said at least one p-n junction comprises a p-type region and an n-type region arranged generally concentrically in a core-shell relation.

24. The method of claim 23, wherein said at least one p-n junction comprises a plurality of p-type regions and n-type regions arranged to form a plurality of generally concentric shells.

25. The method according to claim 23, wherein at least a few of said p-type regions and n-type regions are graded thereamongst.

26. The method according to claim 25, wherein at least a few of said p-type regions and n-type regions are made of a AₓB₁₋ₓ compound, wherein x is from 0 to 1, wherein A and B are different semiconductor elements, and wherein said grading is characterized by a gradually varying value of x as a function of at least one of: (i) a radial direction of said respective elongated nanostructure and (ii) an axial direction of said respective elongated nanostructure.

27. The method according to claim 26, wherein A is silicon and B is germanium.

28. The method according to claim 20, wherein each of at least a portion of said elongated nanostructure comprises an axially graded core, selected to constrain a unidirectional axial motion of charge carriers along said core.

29-32. (canceled)

33. A method of fabricating a photovoltaic cell, comprising:
growing on an electrically conductive substrate a plurality of spaced-apart elongated nanostructures aligned vertically with respect to said substrate, and having at least one p-n junction characterized by a bandgap within the electromagnetic spectrum;
applying an electrically insulating layer on said substrate at a base level of said elongated nanostructures; and
coating each of at least a portion of said elongated nanostructures by an electrically conductive layer, said electrically conductive layer being electrically isolated from said substrate by said electrically insulating layer.

34-46. (canceled)
